(19) United States
(12) Patent Application Publication
(10) Pub. No.: US 2007/0239374 A1
(43) Pub. Date: Oct. 11, 2007

(54) System and Method for Monitroing a Vehicle Battery

(75) Inventors: Thomas J. Dougherty, Waukesha, WI (US); William J. Wruck, Whitefish Bay, WI (US); Deeyu C. Chen, Oak Creek, WI (US); Ronald C. Miles, Whitefish Bay, WI (US); Michael L. Thompson, East Troy, WI (US)

Correspondence Address: FOLEY & LARDNER LLP, 777 EAST WISCONSIN AVENUE, MILWAUKEE, WI, 53202-5306, US

(73) Assignee: Johnson Controls Technology Company

(21) Appl. No.: 10/587,197

(22) PCT Filed: Jan. 26, 2005
(86) PCT No.: PCT/US05/02428

§ 371 Date: Apr. 20, 2007

Related U.S. Application Data
(60) Provisional application No. 60/539,239, filed on Jan. 26, 2004.

(51) Int. Cl. G01R 31/36

(52) U.S. Cl. 702/63

(57) ABSTRACT

A method for monitoring a battery installed in a vehicle includes utilizing a system provided within the vehicle to determine that a test of the battery should be performed when a first condition is satisfied. The method also includes electrically coupling at least one vehicle load to the battery and utilizing the system to analyze the response of the battery to the at least one vehicle load coupled to the battery. The system may be utilized to determine the state of health of the battery.

### CROSS-REFERENCE TO RELATED APPLICATIONS

This application claims the benefit of U.S. Provisional Application No. 60/539,239, filed Jan. 26, 2004, the entire disclosure of which is incorporated herein by reference.

### BACKGROUND

The present invention relates to monitoring and management systems and methods for batteries (e.g., lead-acid batteries such as batteries for vehicle starting, lighting, and ignition applications; marine batteries; commercial batteries; industrial batteries; batteries for use with hybrid-electric vehicles; etc.). Specifically, the present inventions relate to systems and methods for analyzing the response of a battery (e.g., voltage response, current response, etc.) to an applied load. The present inventions also relate to battery monitoring and management systems that may be used to determine the deliverable power and energy for a battery.

Various known systems utilize external loads to characterize features of a vehicle battery. For example, a battery charger/tester that is separate from a vehicle and electrically connected to the terminals of a battery may apply a load to the battery in an attempt to determine a battery characteristic. One difficulty with such a system is that constant monitoring of battery response (e.g., while the battery is in service on the road) is not be achieved, since the vehicle must be in the presence of a battery charger/tester unit (e.g., in a service station, etc.) for such monitoring to occur. Accordingly, analysis of the vehicle battery is performed on an infrequent basis corresponding to times when the vehicle owner takes the vehicle in for service. Such infrequent analysis does not allow the vehicle to adjust how the battery is charged and discharged while the battery is in regular use.

It would be advantageous to provide a system and/or method for monitoring and/or managing a vehicle battery that uses loads provided within a vehicle, and without the need to electrically connect the battery to a charger/tester unit. It would also be advantageous to provide a system and/or method for managing the charging and discharging of a battery based on the response of the battery to applied vehicle loads. It would be advantageous to provide a system and/or method having any one or more of these or other advantageous features as will be described more fully herein.

### SUMMARY

The present invention relates to a method for monitoring a battery installed in a vehicle. The method includes utilizing a system provided within the vehicle to determine that a test of the battery should be performed when a first condition is satisfied. The method also includes electrically coupling at least one vehicle load to the battery and utilizing the system to analyze the response of the battery to the at least one vehicle load coupled to the battery. The system may be utilized to determine the state of health of the battery.

The present invention also relates to a system for monitoring a vehicle battery using a method such as that recited in the preceding paragraph. The system includes a battery installed within a vehicle, a system that may be selectively electrically coupled to the battery for carrying out the method, and a vehicle electrical system comprising a plurality of loads that may be selectively electrically coupled to and decoupled from the battery.

### BRIEF DESCRIPTION OF THE DRAWINGS

FIG. 1 is a schematic view showing a system according to an exemplary embodiment.

FIG. 2 is a schematic graphical representation showing the voltage response of a battery upon the application of various loads according to an exemplary embodiment.

FIG. 3 is a flow chart showing the steps of a routine for analyzing a battery response according to an exemplary embodiment.

FIG. 4 is a flow chart showing the steps of a routine for analyzing a battery response according to another exemplary embodiment.

FIG. 5 is a graphical representation showing the voltage and current response of a good battery during an extended cranking test.

FIG. 6 is a graphical representation showing the voltage and current response of a bad battery during an extended cranking test.

FIG. 7 is another graphical representation showing the voltage and current response of a bad battery during an extended cranking test.

FIG. 8 is a flow chart showing the steps of a routine to characterize a battery that has been newly installed in a vehicle.

### DETAILED DESCRIPTION OF EXEMPLARY EMBODIMENTS

Battery voltage and/or current (and/or other parameters of the battery) may vary depending on the number of vehicle loads drawing power from the battery. For example, if the battery is supplying power to a vehicle load such as a window defroster, the battery voltage will be less than if the battery were not coupled to any loads. The response of the battery (e.g., the voltage response, current response, etc.) may be measured or analyzed to determine various battery parameters that may be utilized in predicting the deliverable power and energy of the battery, the estimated remaining life of the battery, and/or other battery features and/or parameters.

The response of a battery to various applied loads may be provided as input signals from sensors coupled to the battery (e.g., electrically coupled to the battery) to a battery monitoring or management system that may be coupled to a battery and/or a vehicle communication system (e.g., a bus such as a CAN bus, etc.). Such input signals may be representative of various parameters of the battery, such as the voltage and/or current of the battery. The battery monitoring or management system may also provide output signals to instruct various components and/or systems of the vehicle to take further action. For example, the battery monitoring or management system may provide output signals to a voltage regulator to provide a higher level of charging to the battery during operation of the vehicle, such that the battery is more highly charged that otherwise would occurred under similar circumstances.

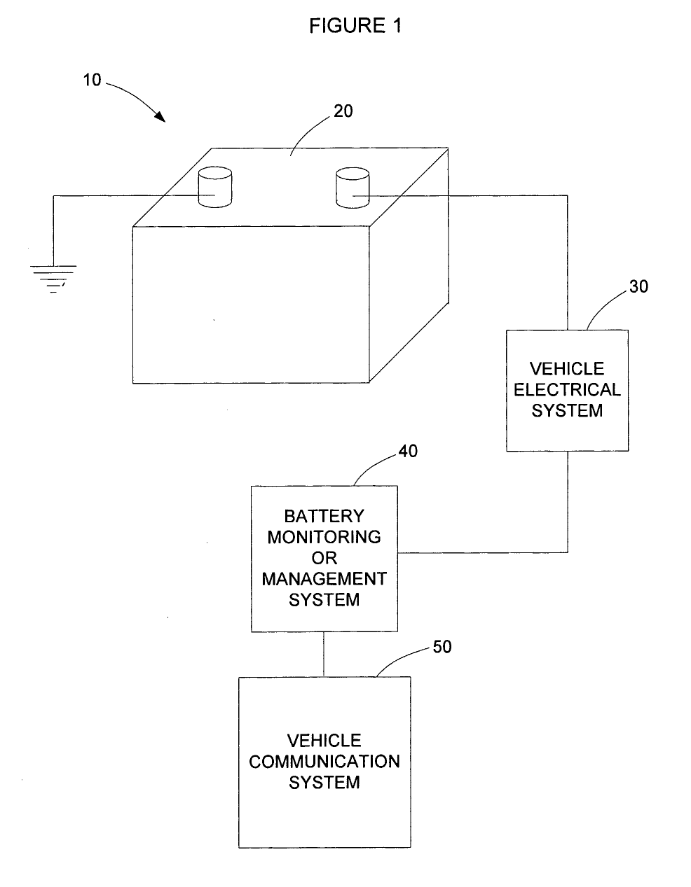

FIG. 1 shows a schematic view of a system 10 according to an exemplary embodiment. System 10 includes a battery system 20 including one or more batteries. For ease of description, the term “battery” as used herein should be understood to refer to a battery system that includes one or more batteries.

Battery system 20 is coupled to a vehicle electrical system 30 that includes a battery monitoring or management system 40 (e.g., an on-board diagnostic system). Battery monitoring system 40 may be implemented in hardware, software, and/or firmware, and may include a control program. Battery monitoring system 40 may be located in a battery, in a battery control module, in an engine control module, in a vehicle control module, or in any other suitable location.

Battery monitoring system 30 is in communication with a vehicle communication system 50 (e.g., a CAN bus or other type of vehicle communication system, etc.). Vehicle communication system 50 may provide output signals and receive input signals representative of various information, data, etc., from one or more vehicle components. Sensors (not shown) may be provided that provide input signals for the vehicle communication system and/or the battery monitoring system. For example, voltage and/or current sensors may be coupled to battery system 20 to detect voltage and/or current responses of the battery (e.g., in response to an applied load, etc.).

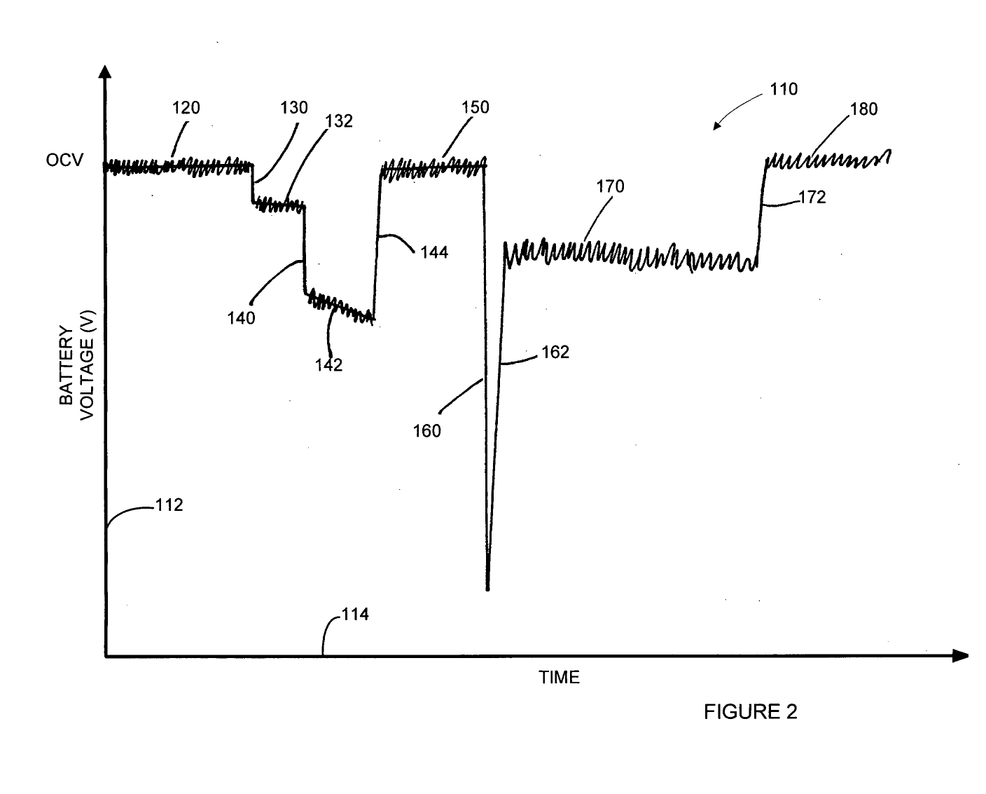

FIG. 2 shows a schematic graphical representation 110 that shows the response of battery voltage with various applied loads. The voltage of a battery is plotted on the ordinate or y-axis 112 and time is plotted on the abscissa or x-axis 114. It should be understood by those reviewing this disclosure that the graphical representation shown in FIG. 2 is theoretical only, and does not reflect any actual measurements of battery voltage. Instead, FIG. 2 is presented to show typical responses to applied loads for purposes of describing the inventions disclosed herein.

It should be noted that the terms “loads” and “vehicle loads” as utilized herein refer, unless otherwise designated, to loads that are part of a vehicle (e.g., loads provided by a window defroster, and engine crank, a sensor coupled to a CAN bus, etc.), as opposed to external loads that may be applied to a battery such as loads that may be included in or connected to a battery tester or other device that may be coupled to the battery for purposes of testing or charging a battery. One advantageous feature of the presently disclosed embodiments is that internal vehicle loads may be used to analyze the battery response to the application of such loads; accordingly, the need to provide an external load (e.g., by a battery tester) is eliminated. By utilizing internal vehicle loads, therefore, the battery monitoring or management system may be entirely contained within the vehicle without the need to utilize external loads.

During a first period reflected as portion 120 of graphical representation 110, the battery has a relatively stable open-circuit voltage, which corresponds to the voltage of the battery with no loads applied to the battery (i.e., no loads from the vehicle are drawing power from the battery).

The application or connection of vehicle loads to the battery may result in a drop in battery voltage that may be reviewed, analyzed, and/or characterized by a battery monitoring or management system according to an exemplary embodiment. Any of a variety of vehicle loads may be connected to the battery to analyze the response of the battery voltage and/or current. For example, relatively low current loads and relatively high current loads may include vehicle interior or exterior lights, a window defroster, a heating and/or air conditioning system, a windshield wiper motor, a vehicle seat heater, a vehicle seat adjustment mechanism, a vehicle entertainment system, a current sensor included as part of the battery monitoring system and/or a CAN bus or other vehicle communication system, or any other load or system that is included in a vehicle that may draw power from the battery.

A relatively low current load applied to the battery results in a drop in voltage shown as portion 130 of graphical representation 110. According to an exemplary embodiment, the relatively low current load has a value of between approximately 3 and 20 amperes (e.g., approximately 10-20 amperes). As the relatively low current load remains applied to the battery, the voltage of the battery gradually decreases, as shown as portion 132 of graphical representation 110. Power drawn from the battery results in a decrease of the voltage of the battery, which is reflected as a slight downward slope in the graphical representation.

A relatively high current load applied to the battery results in a further drop in battery voltage as shown as portion 140 of graphical representation 110, followed by a decreasing voltage shown as portion 142 with continued application of the relatively high current load. The relatively high current load has a value of approximately 50 amperes according to an exemplary embodiment, but may have a value of between approximately 20 and 100 amperes according to other exemplary embodiments.

Although graphical representation 110 illustrates a situation in which the relatively low current load is not removed prior to the application of the relatively high current load (i.e., the high current load is applied in addition to the low current load), according to other exemplary embodiments, the relatively low current load may be removed prior to the application of the relatively high current load. Such a situation may result in a “bounce-back” or recovery voltage in the battery, which would show a relatively quick increase in battery voltage subsequent to removal of the relatively low current load. The level of battery voltage subsequent to the application of the relatively high current load should be greater than if the relatively low current and high current loads are applied concurrently.

Subsequent to the application of the relatively high current load, the relatively high current and low current loads are removed from the battery, and the battery exhibits a recovery or bounce-back voltage shown as an increase in battery voltage in portion 144 of graphical representation 110. With both the relatively high and low current loads removed from the battery, the battery voltage returns to a level that is approximately equal to the open circuit voltage (i.e., the level at which no loads are applied to the battery). According to other exemplary embodiments, the battery voltage may have a value that differs from the open circuit voltage for the battery (e.g., the battery voltage may have declined during application of the loads to the battery such that a portion of the battery voltage is not recovered upon removal of the loads from the battery).

Subsequent to application of the loads to the battery, the engine of the vehicle may be started, which results in a sudden drop in battery voltage such as that reflected as portion 160 in graphical representation 10, followed by a subsequent recovery of battery voltage reflected as portion 162 in graphical representation 110. Continued cranking of the vehicle starter is represented as portion 170 in graphical representation 110. In this manner, the vehicle starting mechanism and cranking action act as a load on the vehicle battery (e.g., the act of starting the battery may apply a large load, such as approximately 200 amperes, to the battery). By extending the cranking time for the battery (i.e., preventing starting until a predetermined time has passed), the voltage response of the battery to extended cranking may be analyzed. For ease of description, such a test is referred to as an extended cranking test herein.

According to an exemplary embodiment, the cranking of the starting mechanism is reflected as a relatively stable battery voltage. According to other exemplary embodiments, cranking may result in a battery voltage profile that differs (e.g., that gradually declines with increasing cranking time, etc.). Once the vehicle is started and cranking has terminated, the battery voltage may recover as reflected in portion 172 to reach a level reflected in portion 180 that approaches the open circuit voltage of the battery. According to other exemplary embodiments, the recovery of the battery may be such that the open circuit voltage of the battery is not obtained, such that the battery voltage subsequent to starting is less than the original open circuit voltage.

It should be noted that according to various exemplary embodiments, one or more of the loads (e.g., a relatively low current load, a relatively high current load, and a vehicle start with extended cranking period) may be applied to the battery and the response of the battery analyzed. For example, according to one exemplary embodiment, a relatively high current response test may be performed without the use of other load response tests. According to another exemplary embodiment, a relatively high current load may be applied to the battery, after which an extended cranking test may be performed. According to other exemplary embodiments, more than one of each test may be performed. For example, two relatively high current loads may be applied to the battery concurrently or individually and the response of the battery analyzed. Any combination of load tests may be utilized according to various exemplary embodiments, in any of a variety of orders that may be selected according to various considerations.

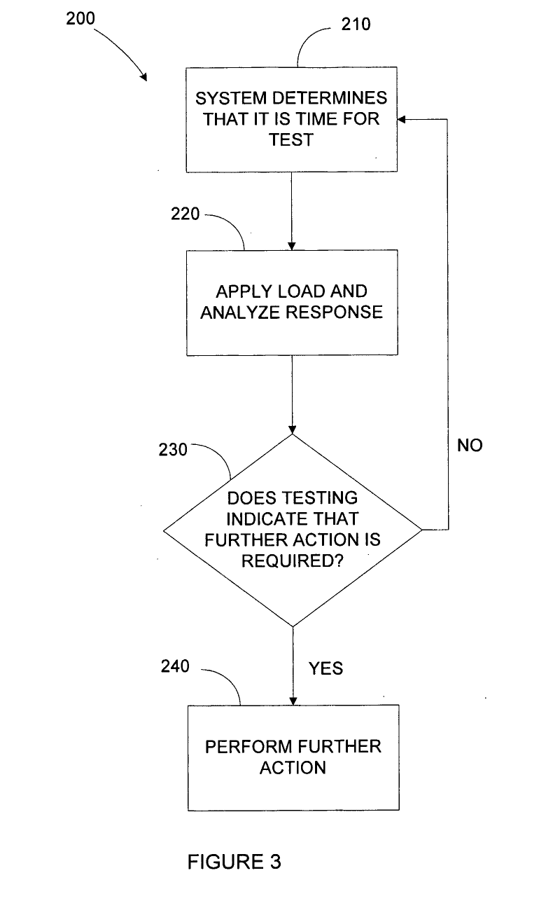

FIG. 3 shows a flow chart 200 that details the steps for analyzing or testing the response of a battery to the application of a vehicle load according to an exemplary embodiment. The system determines that it is appropriate to test the response of the battery to an applied load (step 210). According to various exemplary embodiments, the determination to test or analyze the response of the battery may be made based on a variety of factors. According to one exemplary embodiment, the system may determine that a test is required after a certain time has elapsed that the battery is in the vehicle (e.g., at regular intervals such as every three months or some other period of time; after the battery has been in the vehicle for a period of time, such as one year, after which such a determination will be made at regular intervals, etc.).

According to another exemplary embodiment, the determination that a test is required may be made after a certain number of vehicle starts have been made. For example, after the vehicle has been started a certain predetermined number of times, the system may determine that a test is required (e.g., after 200 vehicle starts, etc.). Such determination may be made at regular intervals (e.g., every 10 vehicle starts after 200, etc.). According to another exemplary embodiment, the determination to test the battery based on the number of vehicle starts may be made at regular intervals throughout the life of the battery (e.g., not after a predetermined number of starts, but from the beginning of battery usage).

According to another exemplary embodiment, the determination that a test is required may be made in response to an observed condition of the battery. For example, the system may review data received in the form of input signals that indicate that certain battery parameters may be approaching a level that is outside a certain predetermined range of expected values. For example, based on regular analysis of battery responses, the system may determine that the voltage and/or current level for the battery is approaching a lower range of acceptable values for a particular event (e.g., the last vehicle start may have shown a battery voltage level that is on the lower end of a range of values that are considered necessary to provide a vehicle start in the future). Various other parameters may be utilized according to other exemplary embodiments. For example, the system may analyze the slope of the battery voltage with time during the application of a particular load to determine that the slope is larger than expected, which may be indicative or representative of a problem with the battery. If the information or input signals received and analyzed by the system indicate that the battery may have a problem (e.g., low state of charge, state of health, etc.), then the determination may be made that a test of the battery in response to an applied load may be made.

According to another exemplary embodiment, the determination that a test is required may be made in response to a certain number of “weak starts” of the battery. For example, the system may detect that the voltage level for the battery during the last five vehicle starts was at the lower end of a particular predetermined range of acceptable voltage levels, which may result in the determination that a test is required.

According to other exemplary embodiments, other factors may be utilized in making a determination that a test of the battery in response to an applied load is required. For example, the system may utilize the age of the battery (e.g., the time at a particular operating condition such as voltage and temperature), the calendar days of service of the battery, the number of cycles of the battery (i.e., with one cycle corresponding to one complete discharge and re-charge of the battery), etc.

Once it is determined that a test is required to determine the response of the battery to an applied load, one or more loads are applied or electrically connected to the battery (step 220). As described above, any of a variety of loads (e.g., a relatively low current load, a relatively high current load, etc.) may be applied to the battery in any of a variety of sequences. Thus, it is not necessary to apply each of a relatively low current load, a relatively high current load, and an extended cranking load to the battery according to every exemplary embodiment. Instead, one or more of such loads may be applied to the battery according to various exemplary embodiments. It should also be noted that such loads need not be applied relatively close in time to each other for embodiments in which multiple loads are applied. For example, a relatively high or low current load may be applied to the vehicle at a time in which no driver or operator is present in the vehicle, and the extended cranking load may be applied upon the next vehicle start.

A vehicle start and cranking situation also may be utilized to determine the response of the battery to the applied load of the cranking. For example, it may be desirable to provide an extended cranking period (e.g., 15 seconds or longer) during which the effect of the cranking on the battery is analyzed. Such extended cranking may be used in addition to or in place of the application of one or more vehicle loads (e.g., vehicle defrosters, etc.).

According to an exemplary embodiment in which at least one of a relatively low and a relatively high current level vehicle load is electrically coupled to the battery, such application of the load may occur either upon entry of a driver or passenger in the vehicle or at a time when the driver and/or passenger are not present. For example, according to an exemplary embodiment, a driver entering a vehicle will open a door, which may cause a dome light or other systems to operate. In another example, the operation of a wireless key fob may cause one or more vehicle systems, such as a vehicle radio, a seat adjustment mechanism, a climate control system, or other system to operate. The system may determine that a driver and/or passenger has entered or will enter the vehicle in response to an input signal received from a vehicle communication system such as a CAN bus, after which a load is applied to the battery to determine the response of the battery to the applied load prior to starting the vehicle. The determination by the system that the load test is required may be made prior or subsequent to the determination that a driver and/or passenger will or has entered the vehicle.

According to another exemplary embodiment, the relatively low or high current load may be applied to the battery and the response to such load analyzed at a time when there is no driver and/or passenger present. For example, the load may be applied at a time when it is unlikely that a driver and/or passenger will be present (e.g., 2 a.m., etc.). In this manner, the load is applied and the response is analyzed in a manner that will not affect the operation of the vehicle (i.e., the starting of the vehicle is not delayed so that the system may analyze the response of the battery, etc.).

According to another exemplary embodiment, the load to be applied to the battery is a vehicle start with extended (e.g., 15 seconds or more, etc.) cranking. Once it has been determined by the system that a test should be performed on the response of the battery to the applied load, the next vehicle start includes a cranking period that is extended relative to the amount of time that would normally be sufficient to accomplish starting of the vehicle.

Upon application of the load (e.g., relatively low current load, relatively high current load, starting with extended cranking, etc.), the system receives input signals from one or more sensors (e.g., voltage sensors, current sensors, etc.) representative of one or more parameters of the battery (e.g., voltage, current, etc.). The information obtained from the input signals is then compiled and analyzed by the battery monitoring or management system to determine whether further action is required (step 230). The analysis may utilize any of a variety of information to make the determination whether further action is required. For example, one or more lookup tables or lists may be provided that include information relating to the expected response of the battery to a certain applied load. According to other exemplary embodiments, historical information relating to the response of the battery under similar circumstances may be utilized to compare the response of the battery at the present time to the response of the battery at various points in the history of the battery. For example, according to an exemplary embodiment in which the behavior (e.g., response) of the battery is learned throughout its use, information is obtained in the form of input signals at regular intervals or at pre-selected times, cycles, after predetermined events, etc. Such information is stored by the system and utilized to analyze the response of the battery to a particular applied load.

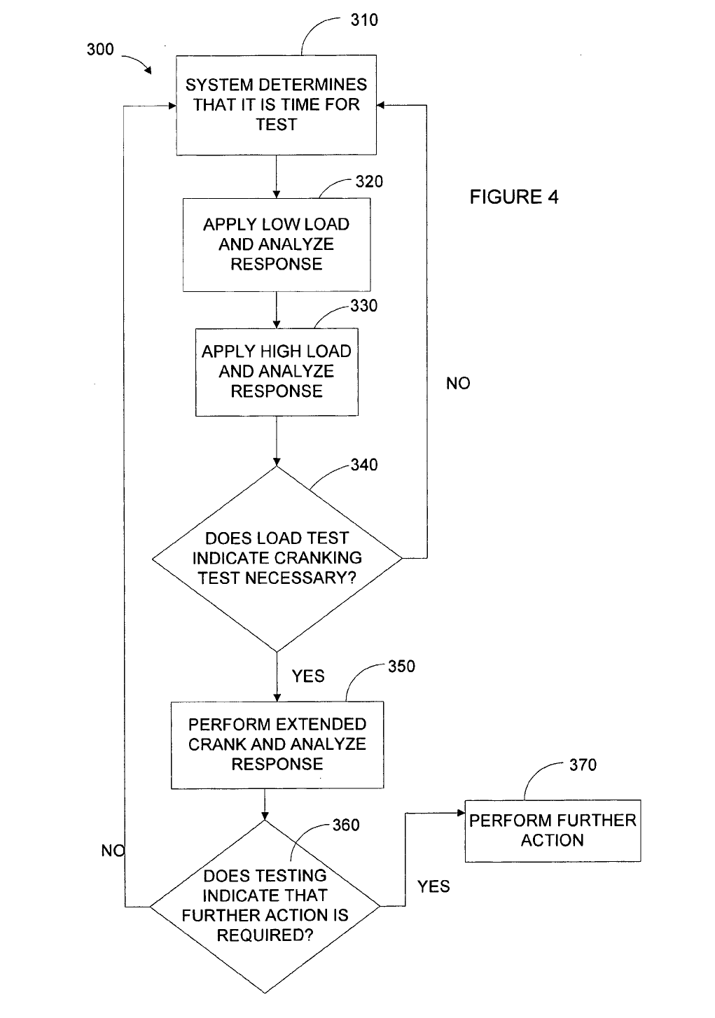

According to an exemplary embodiment, more than one load may be applied to make a determination whether further action is required. For example, rather than utilize the response of the battery only to the application of one of a relatively low current load, a relatively high current load, or a vehicle start with extended crank, the system may utilize data from two or more of these applied loads. FIG. 4, for example, is a flow chart 300 that details a test in which the response to the application of a relatively low current load, a relatively high current load, and a vehicle start with extended cranking is analyzed to make a determination of whether further action should be taken. That is, in a step 310, the system determines that a test of the response of a vehicle battery to applied loads, after which a relatively low current load (step 220) and a relatively high current load (step 330) are applied and the response of the battery is analyzed. In the embodiment shown in FIG. 4, prior to providing a vehicle start with extended cranking, a decision is made in step 340 as to whether the initial information obtained in steps 320 and 330 indicate that a cranking test is necessary (e.g., if the data indicates that there may be a problem with the battery, a subsequent cranking test may be performed). According to another exemplary embodiment, the decision shown in step 340 may not be required, and the cranking step shown in step 350 may not be utilized (i.e., all three load applications may be performed).

One advantageous feature of the embodiment shown in FIG. 4 is that if testing of the response to a relatively low and high current load does not indicate that the battery has a problem, then no test requiring extended vehicle cranking is performed, which in turn will not inconvenience the driver of the vehicle (i.e., the extended cranking test may indicate to the driver that there is a problem with the vehicle, which may not be necessary if the low and high current tests indicate that there is no such problem).

Referring again to FIG. 3, if the testing from one or more of the load applications indicates that there is a problem with the battery, then the battery monitoring system may provide output signals indicating that further action should be taken by the system (step 240 in FIG. 3, and corresponding step 370 in FIG. 4). For example, the system may provide an output signal to instruct the voltage regulator of the vehicle to apply a greater charge to the battery during subsequent vehicle operation in an attempt to charge the battery to an acceptable level. Other actions may also be taken. For example, an output signal in the form of a visual or audible indication or alert may be provided to the driver to indicate that a problem has been exhibited by the battery. Messages such as text messages may be provided to the driver (e.g., on a computer screen or other display such as an LED display on an instrument panel) to indicate that the battery should be replaced or that other action should be taken to ensure proper starting of the vehicle and operation of the battery. In another example, the system may determine that additional testing is required, such that the routine shown in FIG. 3 is repeated to confirm the results before other action is taken. In another example, the engine idle speed may be adjusted to provide additional charging for the battery. In another example, certain vehicle loads (e.g., “nonessential” loads such as vehicle entertainment systems, etc.) may be disabled to prevent further drain of battery voltage. Any of a variety of other actions may be performed by the system to ensure proper starting of the vehicle and/or proper operation of the battery and vehicle electrical system.

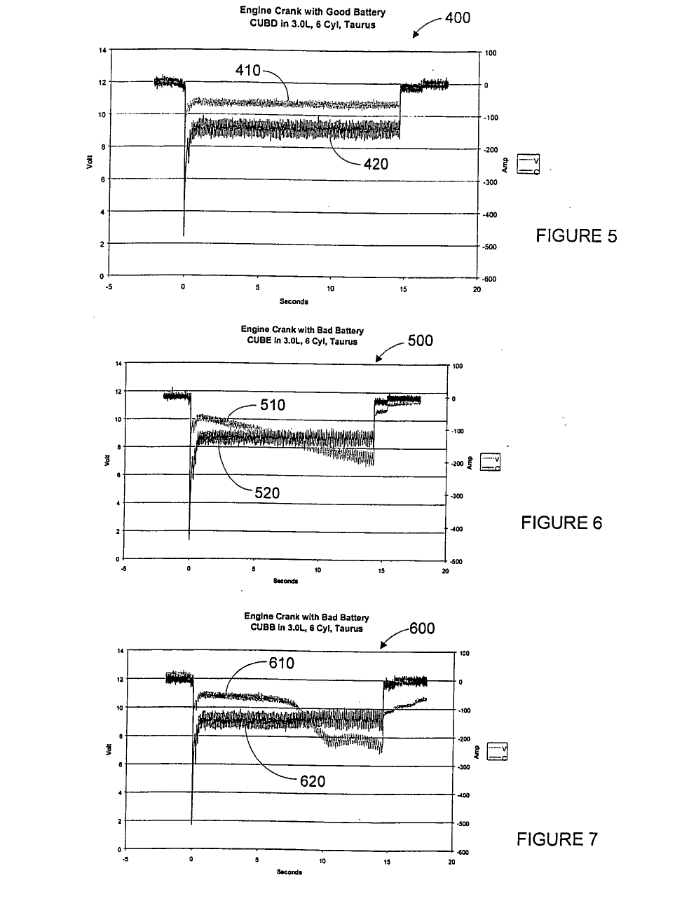

FIGS. 5-7 are graphs provided to illustrate the voltage and current response of various batteries during a start and extended cranking operation. FIG. 5 shows a graphical representation 400 of the voltage response 410 and current response 420 for a “good battery” (e.g., a battery with no identifiable problems exhibited during the test and that should be able to support engine cranking with little or no voltage drop). As shown in FIG. 5, both the voltage and current during the extended cranking period (illustrated as being between approximately 0 and 15 seconds) are relatively constant, as exhibited by the relatively horizontal profile of the data during this period.

In contrast to the data for the “good battery” shown in FIG. 5, FIGS. 6 and 7 show graphs 500, 600 showing the response for “bad batteries” under similar circumstances. For example, FIG. 6 shows a voltage response 510 that declines at a relatively constant rate with time during the cranking period, while the current response 520 is substantially constant. FIG. 7 shows a voltage response 610 that is relatively constant for a period of time before a substantial decrease begins at point 612 (at about 7-8 seconds). Again, the current response is shown as being relatively constant during the cranking period in FIG. 7. Both FIGS. 6 and 7 may indicate that there is a problem with a battery that may be rectified by taking further action (e.g., replacing the battery, providing additional charging to the battery, etc.).

According to one exemplary embodiment, the battery monitoring system determines that the battery is healthy (e.g., a “good battery”) if the battery can support an active cranking load with little or no voltage drop for a period of at least 15 seconds. According to other exemplary embodiments, other determinations as to the health of the battery may be made using different criteria. For example, the health of the battery may be assessed with reference to the voltage response of the battery to an applied relatively low current load, a relatively high current load, and/or a vehicle start with extended cranking period. Any of a variety of load tests may be utilized to make such determination (e.g., two or more separate relatively low current loads and/or high current loads may be applied to the battery concurrently or at different times, etc.).

As described generally above, it may be beneficial to utilize historical information for the battery based on known parameters. For example, it may be helpful to utilize known responses of the battery to certain applied loads. In this manner, deviation from expected values may be quantified and used to determine any degradation in the performance and/or operation of the battery.

It may also be helpful to characterize the battery at other points during the use of the battery. For example, it may be beneficial to characterize the battery after a long period of non-use to determine if any degradation in battery performance and/or operation has occurred. It may also be beneficial to characterize the battery periodically (e.g., once per week, etc.) to determine if any such degradation has occurred. It may also be beneficial to characterize the battery after the system has detected that such degradation has occurred. For example, in the embodiments described above with respect to FIGS. 3 and 4, the system may determine that it is time to perform tests as to how the battery responds to the application of certain loads after a series of “weak starts” or other condition that would seem to indicate that the performance and/or operation of the battery has degraded.

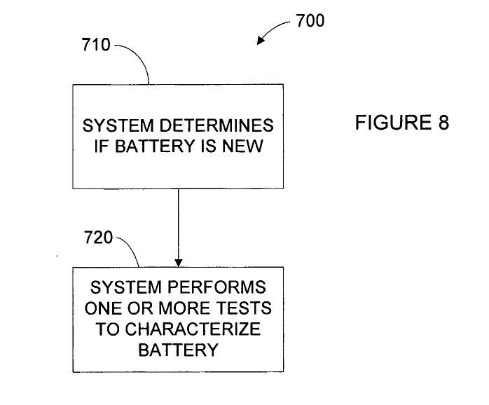

FIG. 8 shows a flow chart 700 for characterizing a new battery. In this manner, the battery monitoring or management system may obtain data in the form of input signals (e.g., current values, voltage values, etc.) that may be used subsequently to determine if the battery is behaving as expected or whether some further action should be taken (e.g., replacing the battery, charging the battery, etc.).

To characterize a “new” battery, the battery monitoring or management system first determines that the battery is new to the vehicle (step 710). That is, while the battery may be newly installed in the vehicle, this does not necessarily mean that the battery is in a new and fully-charged state. For example, the battery may have been obtained from another vehicle after it had been used for a period of time or from a store shelf where it had been kept for a period of time. Such extended use and/or storage may act to degrade the parameters of the vehicle (e.g., the battery may not hold a charge in the same manner as if it were a new battery).

Various methods may be utilized to determine if the battery is newly installed in the vehicle. According to an exemplary embodiment, the battery monitoring or management system may obtain an input signal from an input device (e.g., a keyboard, computer user interface, or other device) that indicates that the battery has been newly installed in the vehicle. Various input devices may be utilized in this regard, including laptop computers or other computing devices, etc. In this manner, the battery monitoring or management system receives a “reset” signal that indicates that the battery should be characterized as a battery that is newly installed in the vehicle.

According to another exemplary embodiment, the battery monitoring or management system may infer the fact that a battery has been newly provided in the vehicle. For example, when a battery is removed from the vehicle and replaced with another battery, various vehicle systems will lose power. Such loss of power may be detected by the battery monitoring or management system. According to one embodiment, the battery monitoring system may assume that a newly-installed battery is present and may proceed to characterize the battery. According to another exemplary embodiment, the battery monitoring system may utilize the fact that a power outage has occurred and then perform one or more tests to characterize the battery. The results of these tests may be compared to data from similar tests obtained prior to the power outage, at which point a comparison may be made between the “old” data and the “new” data to determine if indeed a different battery has been installed in the vehicle. According to this embodiment, a limited number of tests may be performed to make this determination, after which additional tests may be performed to further characterize the battery in the event that it is determined based on the initial tests that a different battery has been installed.

Once it is determined that a different battery has been installed in the vehicle (according to one of the methods described above or another method), the battery monitoring system performs one or more additional tests to characterize the battery (step 720). Any of a variety of tests may be performed to characterize the battery in any order.

One exemplary test that may be performed is a test to determine the cranking profile of the battery. Such a cranking test may be a start and delayed or extended cranking test similar to that described above, in which the vehicle is prevented from starting for a predetermined amount of time (e.g., 15 seconds) during which cranking proceeds. The voltage and/or current response of the battery may be analyzed during this period, after which the vehicle is allowed to start. Such a cranking test may be performed one or more times to provide inputs for the characterization of the battery.

Another example of a test to characterize the battery is the response of the battery to a load (e.g., the voltage and/or current response to the load). Such a test may include a load response test that utilizes one or more relatively low current loads and/or one or more relatively high current loads with the engine off, such as that described above. In another example, the response to one or more loads may be analyzed when the engine is running and the alternator is turned off such that the load response can be isolated and analyzed. The duration of the application of such loads may be varied according to various exemplary embodiments.

In another example, the charge current acceptance of the battery may be analyzed (e.g., while the engine is in operation and the alternator is providing sufficient voltage to charge the battery). In such an example, the alternator and voltage regulator may be set to a relatively high voltage for a relatively short time to test the response of the battery during charging.

Any one or more of these tests may be utilized to characterize the battery, and may be utilized to provide points of comparison over the life of the battery. In this manner, the state of health of the battery may be analyzed at periodic times during the life of the battery to provide a prediction as to the end of life of the battery, the relative state of health and state of charge of the battery, etc. The parameters of the new battery may be utilized to determine if the battery will have the ability to provide adequate charge in critical situations (e.g., starting in cold weather, etc.).

It should be understood by those reviewing this disclosure that the tests utilized to characterize the “new” battery may be performed at other points in the life of the battery (e.g., at regular predetermined intervals, after a period of non-use, after the system detects that an event has occurred that may have resulted in degraded performance and/or operation, etc.). In such cases, according to an alternative embodiment, the system may adjust the expected parameters of the battery (e.g., the expected voltage or current responses, etc., stored in a lookup table or otherwise available to the system) based on the age of the battery. In this manner, the natural aging of the battery may be taken into account in assessing the state of health of the battery.

As another exemplary embodiment, rather than characterizing the battery utilizing a series of tests (e.g., a new battery), data about the battery and its characteristics can be entered to the battery monitor (using various input devices, lookup tables stored in memory, etc.), the energy management system, the engine management system, or the vehicle computer directly. For example, the data may be entered by providing a code number via an electrical switch that would be recognized by the electrical system. For example, a switch on the radio could be tapped to set up the data entry mode then to enter code values. The computer would contain a small look-up table that would reference the entered code number to a battery characteristic value.

It should be noted that the information obtained from any of the tests described herein may be utilized by the battery monitoring system to provide an output signal that indicates that further action, such as replacement of the battery, should be taken. For example, where a new battery is installed in the vehicle but subsequent testing indicates that the battery does not have enough charge to start in cold weather conditions, the battery monitoring system may send an output signal that indicates that the battery should be replaced.

The input signals (or combination of input signals) may be representative of conditions or states of the battery system such as voltage of the battery, current drawn by loads connected to the battery, resistance of the battery, temperature of the battery, time, etc. according to any preferred or alternative embodiments. The input signals may also relate to a characteristic of the battery (such as model number, purchase date, installation date, size, capacity, cold cranking capability rating, reserve capacity rating, etc.) according to any preferred or alternative embodiment. The range of the pre-determined values that are compared to the input signals by the battery management system may be preprogrammed or determined during operation, use, testing, etc. of the vehicle according to any preferred or alternative embodiments. The range of the pre-determined values may be adjusted or calibrated over time according to any preferred or alternative embodiments. The “other devices” for providing inputs to the battery management system may comprise an input device such as a keyboard, display (e.g. touch screen), etc. according to alternative embodiments. The other devices may include a “remote connection” to the battery management system such as a wireless device (e.g. HomeLink (TM) wireless control system, key fob, cellular or digital device, etc.) communicated by a variety of methods and protocols (e.g. infrared, radio frequency, Bluetooth, Wide Application Protocol, etc.) according to alternative embodiments. The “other devices” may comprise a magnetically coupled communication port such as a Manual Swipe Magnetic Card Low-Co Reader/Writer model no. RS-232 commercially available from Uniform Industrial Corp., Fremont, Calif., USA according to a particularly preferred embodiment.

The battery management system may comprise a computing device, microprocessor, controller or programmable logic controller (PLC) for implementing a control program, and which provides output signals based on input signals provided by a sensor or that are otherwise acquired. Any suitable computing device of any type may be included in the battery management system according to alternative embodiments. For example, computing devices of a type that may comprise a microprocessor, microcomputer or programmable digital processor, with associated software, operating systems and/or any other associated programs to implement the control program may be employed. The controller and its associated control program may be implemented in hardware, software, firmware, or a combination thereof, or in a central program implemented in any of a variety of forms according to alternative embodiments. A single control system may regulate the controller for the battery management system and the controller for the vehicle according to an alternative embodiment.

The use of the terms battery “management,” “battery management system,” “monitoring,” and “battery monitoring system” are not intended as terms of limitation insofar as any function relating to the battery, including monitoring, managing, charging, discharging, recharging, conditioning, connecting, disconnecting, reconnecting, etc., is intended to be within the scope of such terms.

It will be recognized by those of ordinary skill in the art reviewing this disclosure that any of a variety of advantages may be obtained by utilizing one or more of the various exemplary embodiments described herein. For example, according to an exemplary embodiment, a system and/or method may be provided that analyzes the response of a battery to one or more applied loads utilizing only loads provided in a vehicle, as opposed to external loads (e.g., loads provided by battery testers, etc.). Such a system and/or method may utilize, for example, one or more of a relatively low current load, a relatively high current load, a vehicle start with extended cranking, and the like, and may analyze the voltage and/or current response of the battery. The system and/or method may thus be utilized to assess the health of a battery utilizing the voltage and/or current response of the battery to one or more applied loads.

Another advantage of utilizing such systems and/or methods as are disclosed herein is that such systems may determine that one or more vehicle loads should be applied to a battery after determining that such a test should be run based on various parameters (e.g., the time in service of the battery, a prior event that indicates some degradation in battery performance, the number of vehicle starts that the battery has been utilized for, the installation of a new battery, etc.). In this manner, the system may assist in characterizing the battery without the need for intervention by a service technician or mechanic (e.g., the system is contained entirely within the vehicle).

Other advantages may also be obtained. For example, the system and/or method may provide a warning to an operator of a vehicle when the condition of the battery is such that the ability of the battery to support loads or starting operations may be below a predetermined threshold. Such a system may utilize known parameters of a battery (e.g., response to particular loads, etc.) to assess the current performance and/or operation of the battery (i.e., historical data is utilized to assess current battery performance and/or operation). In this manner, the system may be said to “learn” various parameters of the battery during the life of the battery.

It is important to note that the system and method described herein is illustrative only. Although only a few embodiments of the present inventions have been described in detail in this disclosure, those skilled in the art who review this disclosure will readily appreciate that many modifications are possible without materially departing from the novel teachings and advantages of the subject matter recited in the claims. Accordingly, all such modifications are intended to be included within the scope of the present invention as defined in the appended claims. The order or sequence of any process or method steps may be varied or re-sequenced according to alternative embodiments. Items or features described as being connected or coupled are intended to include both direct and indirect connections or coupling. Other substitutions, modifications, changes and omissions may be made in the design, operating conditions and arrangement of the preferred and other exemplary embodiments without departing from the scope of the present inventions.

What is claimed is:

1. A method for monitoring a battery installed in a vehicle comprising:
utilizing a system provided within the vehicle to determine that a test of the battery should be performed when a first condition is satisfied;
electrically coupling at least one vehicle load to the battery; and
utilizing the system to analyze the response of the battery to the at least one vehicle load coupled to the battery;
whereby the system may be utilized to determine the state of health of the battery.

2. The method of claim 1 wherein the system provided within the vehicle comprises a battery monitoring and management system.

3. The method of claim 1 wherein the step of determining that a test of the battery should be performed comprises determining that the battery has been newly installed in the vehicle.

4. The method of claim 3 wherein the step of determining that a test of the battery should be performed comprises receiving an input signal from an input device indicating that the battery is newly installed in the vehicle.

5. The method of claim 3 wherein the step of determining that a test of the battery should be performed comprises inferring that the battery is newly installed in the vehicle.

6. The method of claim 5 wherein the step of inferring that the battery is newly installed in the vehicle comprises determining that at least one vehicle system has lost power.

7. The method of claim 6 wherein the step inferring that the battery is newly installed in the vehicle further comprises testing the battery and comparing results of the testing with results of testing prior to the power loss to determine that a different battery has been installed.

8. The method of claim 1 wherein the step of determining that a test of the battery should be performed comprises determining that a predetermined amount of time has passed.

9. The method of claim 8 wherein the predetermined amount of time comprises a predetermined amount of time since the battery was last used.

10. The method of claim 1 wherein the step of determining that a test of the battery should be performed comprises determining that the battery has been used for a predetermined number of vehicle starts.

11. The method of claim 1 wherein the step of determining that a test of the battery should be performed comprises determining that the vehicle has experienced a predetermined number of weak starts.

12. The method of claim 1 wherein the step of determining that a test of the battery should be performed comprises determining that the battery has been cycled a predetermined number of times.

13. The method of claim 1 wherein the first condition comprises at least one of a voltage level of the battery approaching a predetermined threshold, the current level of the battery approaching a predetermined threshold, and a slope of the voltage of the battery with time approaching a predetermined threshold.

14. The method of claim 1 wherein the step of electrically coupling at least one vehicle load to the battery comprises sending a signal from the system to couple the at least one vehicle load to the battery.

15. The method of claim 1 wherein the step of electrically coupling at least one vehicle load to the battery comprises electrically coupling at least one relatively low current load and at least one relatively high current load to the battery.

16. The method of claim 15 wherein the step of electrically coupling at least one relatively low current load and at least one relatively high current load to the battery comprises applying a first load to the battery, removing the first load from the battery, and applying a second load to the battery.

17. The method of claim 15 wherein the step of electrically coupling at least one relatively low current load and at least one relatively high current load to the battery comprises concurrently applying both the low current load and the high current load to the battery.

18. The method of claim 15 wherein the relatively high current load is between approximately 3 and 20 amperes and the relatively low current load is between approximately 20 and 100 amperes.

19. The method of claim 1 wherein the at least one vehicle load comprises at least one load applied by a device selected from the group consisting of a window defroster, an air conditioning system, a windshield wiper motor, a vehicle seat heater, a vehicle seat adjustment mechanism, and a vehicle entertainment system.

20. The method of claim 1 wherein the at least one vehicle load comprises at least one load resulting from an extended engine crank.

21. The method of claim 1 wherein the at least one vehicle load comprises at least one load provided by a sensor coupled to a vehicle communication system.

22. The method of claim 21 wherein the sensor coupled to a vehicle communication system comprises a current sensor.

23. The method of claim 1 wherein the step of analyzing the response of the battery to the at least one vehicle load coupled to the battery comprises analyzing the voltage response of the battery to the at least one vehicle load.

24. The method of claim 1 wherein the step of analyzing the response of the battery to the at least one vehicle load coupled to the battery comprises analyzing the current response of the battery to the at least one vehicle load.

25. The method of claim 1 wherein the step of analyzing the response of the battery to the at least one vehicle load coupled to the battery comprises analyzing the charge current acceptance of the battery when the engine of the vehicle is in operation and the alternator is providing sufficient voltage to charge the battery.

26. The method of claim 1 wherein the step of analyzing the response of the battery to the at least one vehicle load coupled to the battery comprises comparing an input signal received from the battery to historical information for the battery.

27. The method of claim 1 wherein the step of analyzing the response of the battery to the at least one vehicle load coupled to the battery comprises comparing an input signal received from the battery to information included in a lookup table.

28. The method of claim 1 further comprising providing an output signal if the battery is determined by the system to satisfy a second condition.

29. The method of claim 28 wherein the output signal comprises a signal to disconnect one or more loads from the battery.

30. The method of claim 28 wherein the output signal comprises at least one signal selected from the group consisting of a signal to instruct a voltage regulator to apply a greater charge to the battery and a signal to alter the idle speed of the vehicle.

31. The method of claim 28 wherein the output signal is at least one of a visual and an audible signal.

32. The method of claim 28 wherein the step of providing an output signal if the battery is determined by the system to satisfy a second condition comprises determining that the battery cannot support engine cranking for a predetermined amount of time.

33. The method of claim 28 wherein the step of providing an output signal if the battery is determined by the system to satisfy a second condition comprises determining that at least one of the current and the voltage of the battery declines during application of the at least one vehicle load by a predetermined amount.

34. The method of claim 28 wherein the output signal comprises at least one of a visual signal and an audible signal.

35. A system for monitoring a vehicle battery using a method as recited in any of the preceding claims, the system comprising:
a battery installed within a vehicle;
a system that may be selectively electrically coupled to the battery for carrying out the method; and
a vehicle electrical system comprising a plurality of loads that may be selectively electrically coupled to and decoupled from the battery.

36. The system of claim 35 wherein the vehicle electrical system comprises a plurality of relatively high current loads and a plurality of relatively low current loads.

37. The system of claim 35 wherein the plurality of loads comprise at least one vehicle load selected from the group consisting of a window defroster, an air conditioning system, a windshield wiper motor, a vehicle seat heater, a vehicle seat adjustment mechanism, a vehicle entertainment system, and a sensor coupled to a vehicle communication system.
